(19) United States
(12) Patent Application Publication
(10) Pub. No.: US 2024/0120191 A1
(43) Pub. Date: Apr. 11, 2024

(54) METHOD FOR PREPARING THE RESIDUE OF A DONOR SUBSTRATE, A LAYER OF WHICH HAS BEEN REMOVED BY DELAMINATION

(71) Applicant: Soitec, Bernin (FR)

(72) Inventors: Isabelle Huyet, Crolles (FR); Luciana Capello, Grenoble (FR)

(21) Appl. No.: 18/263,802

(22) PCT Filed: Feb. 14, 2022
(86) PCT No.: PCT/FR2022/050260

§ 371 Date: Aug. 1, 2023

(30) Foreign Application Priority Data
Feb. 23, 2021 (FR) 2101738

(51) Int. Cl. H01L 21/02

(52) U.S. Cl. CPC H01L 21/02032; H01L 21/02008

(57) ABSTRACT

A method is used for preparing the residue of a donor substrate, the residue comprising, on a peripheral zone of a main face, a peripheral ring. The method comprises: a first step of removing at least part of the peripheral ring; a second step of processing the main face of the residue aiming to remove a surface layer; a third step, after the second step, of grinding the peripheral zone of the main face of the residue, the third grinding step aiming to reduce the elevation of the peripheral zone.

### CROSS-REFERENCE TO RELATED APPLICATIONS

This application is a national phase entry under 35 U.S.C. § 371 of International Patent Application PCT/FR2022/050260, filed Feb. 14, 2022, designating the United States of America and published as International Patent Publication WO 2022/180321 A1 on Sep. 1, 2022, which claims the benefit under Article 8 of the Patent Cooperation Treaty of French Patent Application Serial No. FR2101738, filed Feb. 23, 2021.

### TECHNICAL FIELD

The present disclosure relates to a method for preparing a donor substrate residue.

### BACKGROUND

Document US 2020/0186117 describes a method for preparing a thin layer that comprises preliminary formation of a composite donor substrate formed by a thick layer of a material on an intermediate support, removing a thin layer from the thick layer of the donor substrate and transferring it to a final support. The removal and transfer steps are implemented by way of the Smart Cut™ technology.

This preparation method is particularly suitable when the material forming the thin layer has a thermal expansion coefficient that is quite different from that forming the final support.

The steps of removing and transferring the thin layer comprise introducing light species into the donor substrate, in this case into the thick layer of the composite donor substrate, through a face (or surface), called “main face,” of this substrate in order to form an embedded fragile plane. The layer to be transferred is defined between this embedded fragile plane and the main surface of the donor substrate. In a subsequent step, the donor substrate is assembled on the final support via its main surface, and heat treatment is applied to the assembly, optionally supplemented by the application of mechanical forces, in order to detach the thin layer at the fragile plane and transfer it onto the final support.

The residue of the donor substrate, i.e., the remaining part of this substrate after the thin layer has been removed, can be reconditioned in order to be used in another removal-reconditioning cycle. Such methods for reconditioning a residue obtained on completion of the Smart Cut™ method are known, for example, from documents EP 1427002, EP 1427001, US 2009/0061545, US 2010/0200854, US 2018/0033609. These methods generally attempt to remove a peripheral step, often referred to as the ring, corresponding to the peripheral portion of the donor substrate that is not transferred to the final support, and to prepare the main surface of the residue in order to remove surface defects generated by the material fracturing at the fragile plane.

In the case of the method proposed in document US 2020/0186117, since the thick layer and the intermediate support have different thermal expansion coefficients, the composite donor substrate tends to have a curvature conferring a generally convex shape thereto, with the main surface (the exposed face of the thick layer) of this substrate being slightly curved outwards.

When the assembly step is carried out by molecular adhesion, the donor substrate is brought into contact with the final support at the apex of the convexity, which is located in a central portion of the main surface of this substrate. A bonding wave is then initiated that tends to bring the two facing surfaces into contact with each other, with this wave concentrically propagating from the point of initial contact toward the outer edges of the donor substrate and the final support.

Such a configuration tends to reveal bonding defects at the interface between the donor substrate and the final support, with these defects assuming the form of small bubbles disposed close to the edges of the assembly, at the propagation end of the bonding wave. These bubbles locally prevent the donor substrate from properly adhering to the final support, and as a result the portions of the thin layer overhanging these defects or in the vicinity thereof are not fully removed and transferred to the final support. Therefore, the thin layer in turn exhibits defects, of the “hole” type, or have a very irregular outline.

It has been noted that the density of the holes in the thin layer, or the uneven nature of the outline of the thin layer, tended to increase with the level of recycling of the donor substrate, i.e., the number of removal-reconditioning cycles undertaken on this substrate.

Of course, this defectiveness is undesirable and, if it exceeds a specified threshold, the hybrid substrate made up of the thin layer and of the final support cannot be used. At the same time, it is economically beneficial for the same substrate to be able to be used a significant number of times, in particular, when a composite donor substrate is used, since this is much more expensive to prepare compared to the cost of reconditioning the residue.

### BRIEF SUMMARY

An aim of the present disclosure is to allow a donor substrate to be used many times, with this multiple use nevertheless limiting the degradation of the quality of the removed and transferred thin layer, as has been noted when the methods of the prior art are used. The present disclosure is of particular interest when the donor substrate is a hybrid substrate, formed by a thick layer disposed on an intermediate support.

In order to achieve this aim, the subject matter of the present disclosure proposes a method for preparing the residue of a donor substrate, with a layer having been removed from the donor substrate by delamination at a fragile plane formed by the introduction of light species, the residue comprising, on a peripheral zone of a main surface, a peripheral ring corresponding to an unremoved part of the donor substrate.

The method comprises:
a first step of removing at least part of the peripheral ring;
a second step of processing the main surface of the residue aiming to remove a surface layer;
a third step, after the second step, of ion etching grinding the peripheral zone of the main surface of the residue, the third grinding step aiming to reduce the elevation of the peripheral zone.

According to other advantageous and non-limiting features of the present disclosure, taken individually or according to any technically feasible combination:
the second processing step is after the first removal step;
the first step is implemented by grinding the peripheral ring;
the second step is implemented by chemical-mechanical polishing of the main surface;
the thickness of the removed surface layer is less than 5 microns;
the ion etching comprises argon ions;
the third grinding step aims to shape the peripheral zone to a determined profile;
the peripheral zone has, on completion of the third grinding step, a maximum elevation that is less than or equal to the elevation of a mean elevation plane of the central portion;
the residue comprises a thick layer of material disposed on an intermediate support;
the material of the thick layer is a ferroelectric material;
the thick layer is assembled on the intermediate support by means of a layer of an adhesive material.

### BRIEF DESCRIPTION OF THE DRAWINGS

Further features and advantages of the present disclosure will become apparent from the following detailed description of the present disclosure with reference to the accompanying figures, in which:

FIGS. 1A and 1B schematically show a residue of a donor substrate;

FIG. 2A shows a residue following the application of a first removal step of a preparation method according to the present disclosure;

FIG. 2B shows a residue following the application of a second processing step of a preparation method according to the present disclosure;

FIG. 2C shows a reconditioned residue following the application of a preparation method according to the present disclosure;

FIG. 3 shows the steps of a method for removing and transferring a thin layer that can use a residue prepared according to the present disclosure.

### DETAILED DESCRIPTION

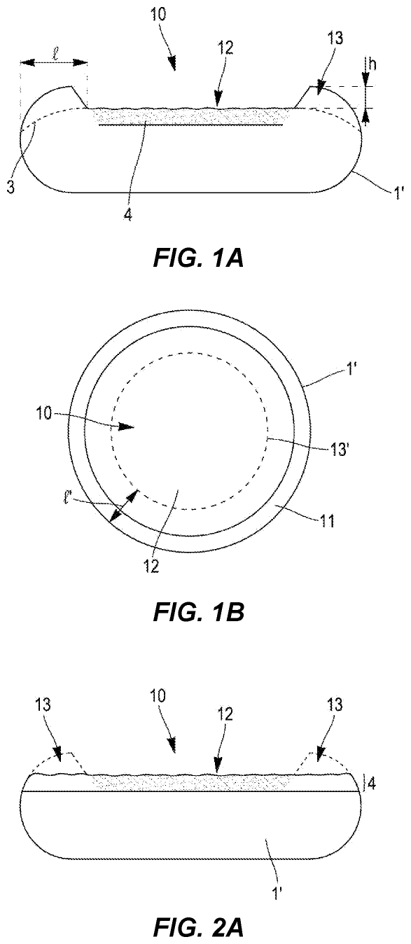

FIGS. 1A and 1B schematically show a residue 1′ of a donor substrate, i.e., a substrate that has had a thin layer removed by delamination at a fragile plane formed by the introduction of light species, in accordance with the steps of a method implementing the Smart Cut™ technology.

A peripheral ring 11 is located on the main face 10 of this residue 1′, which ring is annular in the case of the example shown, in which the residue 1′ is in the form of a circular wafer, corresponding to an unremoved part of the donor substrate. More specifically, the peripheral ring 11 is housed in a peripheral zone 13 of the residue 1′ and corresponds to the portion of the thin layer that is defined in the donor substrate that did not sufficiently adhere with the final support during the assembly step of the transfer method and which, as a result, could not be removed from the donor substrate. The cross-section of FIG. 1A shows, below the peripheral ring 11, the fragile plane 2 defining this portion of the unremoved thin layer.

The peripheral ring 11 forms a step, the width 1 of which can range between 0.5 mm and 8 mm and the height h of which can reach between 100 nm and 1.5 microns. The peripheral zone assumes, on the main surface, a width 1′ that is greater than that of the ring, typically 1 to 3 times the width 1 of the ring, and more generally ranging between 0.5 mm and 2.5 cm.

The presence of this step does not allow the residue 1′ to be used directly for the removal of a new thin layer. Furthermore, a central portion 12 of the main surface 10, i.e., the surface contained inside the peripheral ring 11 of the peripheral zone 13, has a particularly rough surface finish and a hardened surface thickness, which also must be prepared before the residue 1′ can be used again. This surface finish of the central portion 12 results from the step of removing the thin layer, with the central portion 12 specifically corresponding to the fragile plane P, created by the light species introduced into the donor substrate, along which the thin layer was removed.

The present disclosure aims to recondition such a residue 1′ in order to make it suitable for further use in an application of a method for removing and transferring a thin layer implementing the Smart Cut™ method. More specifically, the present disclosure attempts to prevent the occurrence of bonding defects, or to limit the density of these defects, at the periphery of the interface formed by assembling a reconditioned donor substrate (more specifically, a reconditioned residue of a donor substrate) on a final substrate.

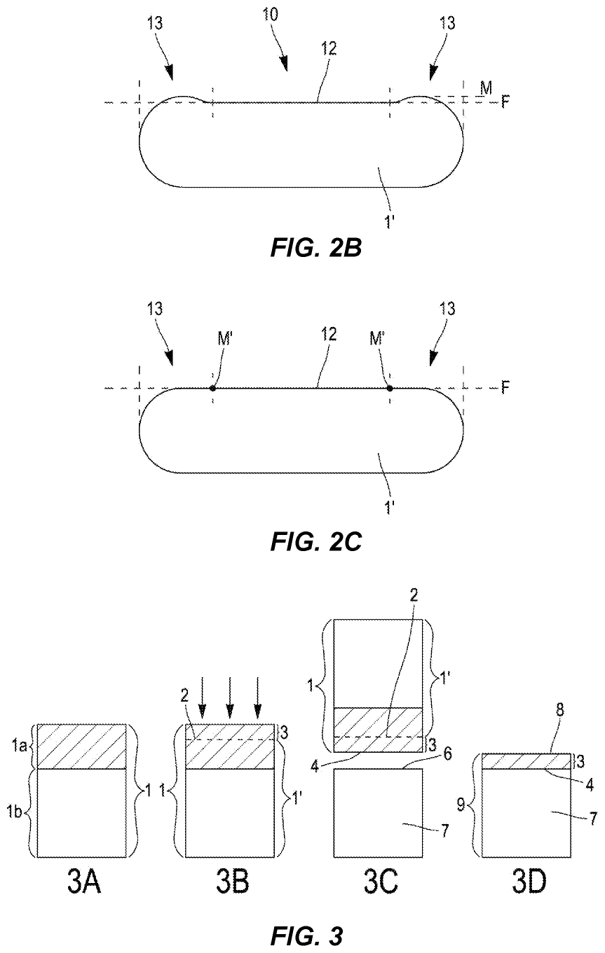

The method for preparing the residue 1′ comprises a first step of removing at least part of the peripheral ring 11. This step can be implemented by grinding. In such an embodiment, a wheel of an item of grinding equipment is provided with abrasive particles (for example, diamonds). It is positioned against the part of the main surface 10 of the residue to be processed, in this case the peripheral ring 11, and is rotated relative to the residue so as to progressively remove the material forming the peripheral ring 11 by mechanical abrasion. This removal exposes the peripheral zone 13 of the residue 1′, as can be seen in FIG. 2A, which shows the residue following the application of this first removal step.

The removal step can implement techniques other than the preferred grinding technique. For example, it can involve a polishing technique, such as double-sided chemical-mechanical polishing.

On completion of this first removal step, the peripheral ring 11 is therefore at least partially eliminated, and the exposed peripheral zone 13 of the peripheral zone of the residue 1′ can have an elevation that is substantially identical to that of the central portion 12 of the residue 1′. The peripheral zone 13 is also particularly rough, in particular, when the ring has been removed by grinding.

Also, the method for preparing the residue 1′ also provides a second step, during which the main face 10 of the residue 1′, i.e., the central portion 12 and the peripheral zone 13 of the residue 1′, is processed in order to remove a surface layer 4. This surface layer 4 is thick enough to contain the hardened thickness of the central portion 12 and, in general, to provide a surface finish for the main surface that is smooth enough to allow it to be assembled on a final support by molecular adhesion. This surface finish can be characterized by roughness of less than 0.5 nm (and advantageously less than 0.3 nm) as a root mean square value over a 5 micron by 5 micron measurement field. This second processing step can be implemented by chemical-mechanical polishing. The thickness of the removed surface layer 4 thus can range between 100 nm and 5 microns.

When the first removal step is separate from the second processing step, the latter is carried out after the removal step. Alternatively, these two steps can be carried out in combination using a technique involving chemical-mechanical polishing of the exposed surface of the residue.

It is also possible to contemplate that these two steps are each carried out using a chemical-mechanical polishing technique, but with each of these steps being carried out with separate parameters and/or consumables (in particular, polishing cloths).

In any case, on completion of the second step of processing the main face 10 of the residue, and as shown in FIG. 2B, a partially reconditioned residue 1′ is available, exhibiting a main surface 10 that is smooth and flat enough to allow it to be adhered to another substrate by molecular adhesion.

However, close inspection of the residue 1′ on completion of the second processing step reveals that it has a “rising” edge flange, i.e., the elevation profile of the exposed surface of this substrate, in its peripheral zone 13, has a maximum M that is greater than the elevation of a mean plane E of the part of the central portion 12 of this substrate, included inside the peripheral zone 13. This elevation profile of the surface of the peripheral zone 13 defining the edge flange can be seen by observing an elevation profile of the exposed surface established along several separate radii and, generally, in all the angular directions of these radii. The point of maximum elevation M of the peripheral zone thus can rise up to 500 nm above the mean plane E of the remainder of the central portion 12 of this substrate (i.e., the portion included inside the boundary of the peripheral zone 13′).

This “rising” edge flange can have many causes. It can be associated with the incomplete removal of the peripheral ring 11 during the first step of the method. However, it also can be associated, even when the peripheral ring has been completely and entirely removed during this first step, with edge effects appearing during the second processing step, in particular, when this is implemented by chemical-mechanical polishing.

It should be noted that this profile does not prevent the partially reconditioned residue of FIG. 2B from being assembled on a final support by molecular adhesion during further application of the method for removing and transferring a thin layer. In particular, its surface is flat and smooth enough for the steps of contacting and propagating a bonding wave to be implemented. However, this “rising” edge flange tends to promote the occurrence of the bonding defects mentioned in the introduction of the present disclosure.

Furthermore, the amplitude of the difference that exists between the maximum elevation M in the peripheral zone 13 and the elevation of the mean plane E of the central portion 12 tends to increase with the level of recycling of the donor substrate, i.e., the number of removal-reconditioning cycles carried out on the same donor substrate.

Also, in order to prevent this phenomenon and to allow such a donor substrate to be reused many times (preferably more than 3 times, or 5 times, or even 10 times), a method for preparing a residue in accordance with the present disclosure provides a third step of rectifying the peripheral zone 13, following the second step of processing the main face 10, with this third step aiming to reduce the elevation of this peripheral zone.

This third step is separate from the first and third steps (and more generally these three steps are separate from each other), i.e., they do not use the same technologies and the same equipment in order to be applied to the residue 1′.

Advantageously, on completion of the third step, the peripheral zone 13 has a maximum elevation M′ that is less than or equal to the elevation of the mean plane E of the central portion 12. The experiments that have been carried out tend to show that such an edge flange, with a “falling” profile, effectively allows bonding defectiveness to be reduced. FIG. 2C shows the residue 1′ after the 3 steps described above have been applied, in the advantageous configuration of the grinding step whereby the peripheral zone 13 has a maximum elevation M′ that is less than or equal to the elevation of the mean plane E of the central portion 12.

It should be noted that a simple reduction in the maximum elevation M′ of the peripheral zone relative to its elevation on completion of the second step, even if it remains higher than that of the mean plane E, can be sufficient to contain the increasing occurrence, with the level of recycling, of the bonding defects. In a very general manner, therefore, this third grinding step attempts to shape the peripheral zone to a determined profile.

In order to allow the peripheral zone 13 to be rectified with the necessary precision, this step is advantageously carried out by a non-mechanical action (more specifically, without any abrasive contact with an external tool), for example, by chemical etching, or preferably by ion beam trimming or ion etching.

According to this approach, ions or clusters of ions are projected onto the peripheral zone 13 of the residue 1′ with sufficient energy, depending on the nature of the constituent material of the residue 1′, to gradually erode (on an atomic level) a surface thickness of this zone. The ions advantageously are heavy ions, such as argon, neon or krypton ions.

The ion beam is therefore directed toward the peripheral zone 13 in order to progressively and very precisely shape this zone to the determined profile. The ion beam is projected onto only part of the peripheral zone 13, and the beam can be relatively moved relative to the residue in order to progressively process this entire zone, with the passage time of the beam over part of the zone determining the amount of material that is removed. Of course, several passes of the beam can be contemplated.

Provision can be made for a mask, for example, made of resin, to be placed outside the peripheral zone 13 in order to avoid degrading the features of the central zone 12 during the application of the third grinding step.

One or more steps of inspecting the residue 1′ can be provided, before, during and/or after the third grinding step, in order to record the elevation profile of the peripheral zone 13 and the central zone 12. In this way, the parameters of the ion etching (or more generally of the third grinding step) can be adjusted in order to effectively control and reproduce the determined elevation profile on the residue 1′.

The substrate of FIG. 2C that is obtained on completion of the application of the third grinding step forms a reconditioned residue 1′ in accordance with the present disclosure, which therefore can be used as a donor substrate 1 in the further application of a method for removing and transferring a thin layer.

### Application Example

This particular example is generally intended to form a hybrid substrate 9 formed by a thin ferromagnetic layer 3 transferred onto a final support 7 made of silicon. It is shown in FIG. 3.

Firstly, a composite donor substrate 1 (step 3A in FIG. 3) is produced, which substrate is formed by an intermediate support 1b made of silicon in the form of a circular, 150 mm diameter wafer, and a thick layer 1a of a ferroelectric material, the thickness of which can range between 5 and 400 microns. The ferroelectric material forming the thick layer 1a is monodomain, and is formed, for example, of LiTaO3, LiNbO3, LiAlO3, BaTiO3, PbZrTiO3, KNbO3, BaZrO3, CaTiO3, PbTiO3 or KTaO3. The crystal orientation of this material is selected as a function of the intended application. Thus, an orientation ranging between 300 and 60° RY, or between 40° and 50° RY, is usually selected when the intention is to use the properties of the transferred thin layer 3 in order to form an SAW filter. However, the present disclosure is by no means limited to a particular crystal orientation.

In this example, the thick layer 1a assumes the same circular shape as the intermediate support and is substantially the same size, so that the donor substrate 1 also assumes a circular shape with a 150 mm diameter. The specific production of this donor substrate 1 can follow the teaching provided in document US 2020/0186117, cited in the introduction of the present disclosure.

Thus, and according to a first approach, the thick layer 1a is assembled on the silicon wafer forming the intermediate support 1b by molecular adhesion. Provision also could have been made for a layer to be inserted between the silicon wafer 1b and the thick layer 1a that facilitates this adhesion (for example, a silicon oxide or nitride).

According to another approach, the thick ferromagnetic layer 1a is held on the silicon wafer 1b by means of a layer of an adhesive material, such as a polymer.

Provision can be made to grind the elevation profile of the free surface of the thick ferromagnetic layer, as proposed in the third step of grinding a residue 1′, in order to provide the donor substrate with a determined profile, for example, a “falling” edge flange as previously described. In this way, the bonding quality is guaranteed during the first iteration of a layer removal method.

Irrespective of the approach that is selected for assembling the thick ferromagnetic layer on the silicon wafer, the composite donor substrate 1 is used as a donor substrate in a method implementing Smart Cut™ technology. To this end, a dose of light species is introduced on the side of the main face (the exposed face of the thick ferromagnetic layer 1a) of the composite substrate 1, resulting in the formation of an embedded fragile plane 2 in the thick layer 1a. This plane defines, with the main face of the donor substrate, the thin ferromagnetic layer 3 to be removed. The nature, the dose of the implanted species and the implantation energy are selected as a function of the thickness of the thin layer to be transferred and of the physico-chemical properties of the thick layer 1a of the donor substrate 1. In the case of a thick layer made of LiTaO3, a dose of hydrogen ranging between 1^{E}16 and 5^{E}17 at/cm² with energy ranging between 30 and 250 keV, can be implanted in order to define a thin layer 3 of the order of 200 to 1,500 nm.

In a subsequent step 3C of the removal method, the main surface of the thick layer 1a is assembled by molecular adhesion with an exposed face of a 150 mm diameter silicon wafer, which therefore is similar to the wafer forming the intermediate support of the donor substrate 1. This wafer forms the final support 7 of the thin layer 3. As already mentioned in the introduction of the present disclosure, the donor substrate 1 can assume a convex shape, with the apex of the convexity facing outwards being disposed on the side of the thick ferromagnetic layer. The deflection of this convexity can be of the order of 200 microns, for the 150 mm wafer taken as an example. As a result, the donor substrate can have an apex that is substantially disposed in the center of the substrate.

During the assembly step, the apex of the donor substrate 1 is brought into contact with the final support 7. Bonding is then initiated by applying a force onto the edge of one of the substrates tending to bring them together. This application of force causes the bonding wave to propagate substantially concentrically from the apex of the donor substrate 1 in contact with the final substrate, toward the peripheral edge of this substrate. This wave causes the two substrates 1, 9 to deform so that their surfaces come into close contact with each other.

In a subsequent step 3D, the assembly formed by the donor substrate and the final support 7 is thermally and/or mechanically processed in order to cause the donor substrate to fracture at the fragile plane 2 in order to delaminate the thin layer 3, remove it and transfer it to the final support 7.

A first hybrid substrate 9 is thus obtained, on the one hand, that is formed by the thin ferromagnetic layer 3 removed from the thick layer 1a and the silicon wafer forming the final support 7. On the other hand, the residue 1′ in line with that of FIG. 1 is also obtained.

This residue 1′ is prepared in accordance with the steps described in the previous general description. In this specific example, the peripheral ring 11 is firstly removed by grinding during the first removal step, in order to bring the elevation of the peripheral zone 13 in which this peripheral ring 11 is housed to the level of the mean plane of the central portion 12. Then, the entire main surface 10 of the residue, i.e., the central portion 12 and the peripheral zone 13, is processed by chemical-mechanical polishing in order to remove up to 1 micron from a surface layer and to reduce the roughness of this surface to less than 0.3 nm as a root mean square value. Finally, the third grinding step is applied to the peripheral zone, in this case to a 1 cm peripheral portion taken from the edge of the wafer, by projecting an argon ion beam in order to reduce the elevation of this peripheral portion.

On completion of these steps, the residue 1′ is fully reconditioned. In addition to surface roughness that is compatible with a molecular adhesion assembly step, it has a “falling” edge flange, i.e., the maximum elevation in the peripheral zone 13 is within or below the mean elevation plane of the central portion 12.

In a subsequent cycle of using this reconditioned substrate, the previously described removal-reconditioning cycles are reapplied in order to provide a plurality of hybrid substrates 9 each comprising a thin ferromagnetic layer 3 disposed on a final support 7. The number of cycles is limited by the remaining thickness of the thick layer 1a of the composite donor substrate 1, it can reach and even exceed 10 cycles, if the thick layer 1a is initially thick enough, for example, being nearly 400 microns thick.

It can be seen that the successively obtained hybrid substrates 9 have defectiveness levels (in particular, originating from adhesive defects at the edges of the substrates) that do not necessarily increase with the number of cycles, i.e., with the level of recycling of the composite donor substrate.

Of course, the present disclosure is not limited to the embodiments and to the example described, and alternative embodiments can be used without departing from the scope of the present disclosure as defined by the claims.

Thus, the present disclosure is applicable to any type of donor substrate that has had a layer removed by delamination at a fragile plane formed by the introduction of light species. This donor substrate does not need to be of the “composite” type, formed by a thick layer resting on an intermediate substrate.

This donor substrate also can assume any nature that is compatible with this type of layer removal. In particular, it can be made up of any semiconductor material, for example, silicon, silicon carbide, germanium, etc.

In general, the substrates can assume any suitable form, and the present disclosure is by no means limited to circular wafers as has been used by way of an example.

1. A method for preparing a residue of a donor substrate, with a thin layer having been removed from the donor substrate by delamination at a fragile plane formed by an introduction of light species, the residue comprising, on a peripheral zone of a main face, a peripheral ring corresponding to an unremoved part of the donor substrate, the method comprising:
a first step of removing at least part of the peripheral ring;
a second step of processing the main face of the residue to remove a surface layer; and
a third step, after the second step, of ion etching grinding the peripheral zone of the main face of the residue, the third reducing an elevation of the peripheral zone.

2. The method of claim 1, wherein the second step is performed after the first step.

3. The method of claim 2, wherein the first step is implemented by grinding the peripheral ring.

4. The method of claim 3, wherein the second comprises chemical-mechanical polishing of the main face.

5. The method of claim 4, wherein a thickness of the removed surface layer is less than 5 microns.

6. The method of claim 5, wherein the ion etching comprises ion etching with argon ions.

7. The method of claim 6, wherein the third step shapes the peripheral zone to a determined profile.

8. The method of claim 7, wherein the peripheral zone has, on completion of the third step, a maximum elevation that is less than or equal to an elevation of a mean elevation plane of a central portion of the donor substrate.

9. The method of claim 8, wherein the residue comprises a thick layer of material disposed on an intermediate support.

10. The method of claim 9, wherein the material of the thick layer is a ferroelectric material.

11. The method of claim 10, wherein the thick layer is assembled on the intermediate support by means of a layer of an adhesive material.

12. The method of claim 1, wherein the first step is implemented by grinding the peripheral ring.

13. The method of claim 1, wherein the second comprises chemical-mechanical polishing of the main face.

14. The method of claim 1, wherein a thickness of the removed surface layer is less than 5 microns.

15. The method of claim 1, wherein the ion etching comprises ion etching with argon ions.

16. The method of claim 1, wherein the third step shapes the peripheral zone to a determined profile.

17. The method of claim 1, wherein the peripheral zone has, on completion of the third step, a maximum elevation that is less than or equal to an elevation of a mean elevation plane of a central portion of the donor substrate.

18. The method of claim 1, wherein the residue comprises a thick layer of material disposed on an intermediate support.

19. The method of claim 18, wherein the material of the thick layer is a ferroelectric material.

20. The method of claim 1, wherein the thick layer is assembled on the intermediate support by means of a layer of an adhesive material.
